(19) United States
(12) Patent Application Publication
(10) Pub. No.: US 2024/0310458 A1
(43) Pub. Date: Sep. 19, 2024

(54) MAGNETIC SIGNAL NOISE MEASURING APPARATUS, METHOD, AND RECORDING MEDIUM

(71) Applicant: ADVANTEST CORPORATION, Tokyo (JP)

(72) Inventors: Yuji OGATA, Miyagi (JP); Tomonori YANAGIDA, Miyagi (JP)

(73) Assignee: ADVANTEST CORPORATION, Tokyo (JP)

(21) Appl. No.: 18/413,516

(22) Filed: Jan. 16, 2024

(30) Foreign Application Priority Data
Mar. 15, 2023 (JP) 2023-040785

(51) Int. Cl. G01R 33/02

(52) U.S. Cl. CPC G01R 33/0206

(57) ABSTRACT

A magnetic signal noise measuring apparatus includes a magnetic measuring section, a tensor decomposing section, and a signal noise segregating section. The magnetic measuring section measures magnetic noise and a magnetic signal generated by a magnetic signal source as a tensor of second or higher order. The tensor decomposing section tensor-decomposes a measurement result from the magnetic measuring section. The signal noise segregating section segregates a decomposition result from the tensor decomposing section into one representing the magnetic signal and one representing the magnetic noise.

### BACKGROUND OF THE INVENTION

### Field of the Invention

The present invention relates to isolating magnetic noise.

### Description of the Related Art

There has been acquiring, with a magnetic sensor, a magnetic signal generated by a magnetic signal source to utilize for estimation of the position of the magnetic signal source, for example. Incidentally, the magnetic signal source may be a stationary ferromagnetic body. In addition, the geomagnetic field, a type of environmental magnetic noise, is approximately a direct current. It is therefore difficult to provide isolation between a magnetic field generated by the magnetic signal source and the geomagnetic field.

It is noted that magnetic noise is difficult to isolate also when the magnetic signal source generates an alternating magnetic signal and there is alternating magnetic noise having the same frequency as the magnetic signal (e.g. utility power source (having a frequency of 50 Hz or 60 Hz)). Reference may be made to WO2012/133185 and Japanese Patent Application Publication Nos. 2022-508506, 2022-521499, 2020-012851, and 2007-139449, for example.

### SUMMARY OF THE INVENTION

It is hence an object of the present invention to isolate magnetic noise.

According to the present invention, a magnetic signal noise measuring apparatus includes: a magnetic measuring section arranged to measure magnetic noise and a magnetic signal generated by a magnetic signal source as a tensor of second or higher order: a tensor decomposing section arranged to tensor-decompose a measurement result from the magnetic measuring section; and a signal noise segregating section arranged to segregate a decomposition result from the tensor decomposing section into one representing the magnetic signal and one representing the magnetic noise.

According to the thus constructed magnetic signal noise measuring apparatus, a magnetic measuring section is arranged to measure magnetic noise and a magnetic signal generated by a magnetic signal source as a tensor of second or higher order. A tensor decomposing section is arranged to tensor-decompose a measurement result from the magnetic measuring section. A signal noise segregating section is arranged to segregate a decomposition result from the tensor decomposing section into one representing the magnetic signal and one representing the magnetic noise.

According to the magnetic signal noise measuring apparatus of the present invention, the magnetic measuring section may be a two-dimensional sensor array with magnetic sensors arranged in a first direction and a second direction that are orthogonal to each other.

According to the magnetic signal noise measuring apparatus of the present invention, the tensor may be of third or higher order, and the magnetic measuring section may be arranged to be moved in a third direction orthogonal to the first direction and the second direction during measurement.

According to the magnetic signal noise measuring apparatus of the present invention, the magnetic measuring section may be a one-dimensional sensor array with magnetic sensors arranged in one of a first direction and a second direction that are orthogonal to each other.

According to the magnetic signal noise measuring apparatus of the present invention, the tensor may be of third or higher order, and the magnetic measuring section may be arranged to be rotated about a rotation axis running in the first direction or the second direction during measurement.

According to the magnetic signal noise measuring apparatus of the present invention, the magnetic measuring section may include magnetic sensors arranged on a predetermined plane and in three or more directions intersecting with each other at one point.

According to the magnetic signal noise measuring apparatus of the present invention, the tensor may be of third or higher order, and the magnetic measuring section may be arranged to be moved in a direction orthogonal to the plane during measurement.

According to the magnetic signal noise measuring apparatus of the present invention, the magnetic measuring section may include a single magnetic sensor.

According to the magnetic signal noise measuring apparatus of the present invention, the magnetic measuring section may be a three-dimensional sensor array with magnetic sensors arranged in a first direction, a second direction, and a third direction that are orthogonal to each other.

According to the magnetic signal noise measuring apparatus of the present invention, the magnetic measuring section may include a plurality of magnetic sensors arranged on a curved plane.

According to the magnetic signal noise measuring apparatus of the present invention, the tensor may be of third or higher order and may provide a result of measurement of the magnetic signal and the magnetic noise associated with a spatial position or the position and time.

According to the magnetic signal noise measuring apparatus of the present invention, the tensor decomposing section may be arranged to provide three or more decomposition results, and a plurality of the decomposition results may be ones representing the magnetic noise having magnetic gradient directions different from each other.

According to the magnetic signal noise measuring apparatus of the present invention, the magnetic noise and the magnetic signal may each have a constant value.

According to the magnetic signal noise measuring apparatus of the present invention, the magnetic noise and the magnetic signal may change over time.

According to the present invention, a magnetic signal noise measuring method with using a magnetic signal noise measuring apparatus having a magnetic measuring section arranged to measure magnetic noise and a magnetic signal generated by a magnetic signal source as a tensor of second or higher order, includes: tensor-decomposing a measurement result from the magnetic measuring section; and segregating a decomposition result from the tensor-decomposing of the measurement result into one representing the magnetic signal and one representing the magnetic noise.

The present invention is a non-transitory computer-readable medium including a program of instructions for execution by a computer to perform a magnetic signal noise measuring process with using a magnetic signal noise measuring apparatus including a magnetic measuring section arranged to measure magnetic noise and a magnetic signal generated by a magnetic signal source as a tensor of second or higher order, the magnetic signal noise measuring process including: tensor-decomposing a measurement result from the magnetic measuring section; and segregating a decomposition result from the tensor-decomposing of the measurement result into one representing the magnetic signal and one representing the magnetic noise.

### BRIEF DESCRIPTION OF THE DRAWINGS

FIG. 1 is a functional block diagram showing the configuration of a magnetic signal noise measuring apparatus 1 according to a first embodiment of the present invention;

FIG. 2 is a plan view of the magnetic measuring section 12 according to the first embodiment:

FIG. 3 is a side view showing how the magnetic measuring section 12 according to the first embodiment is moved:

FIGS. 4 (a) and 4 (b) are plan views of the magnetic measuring section 12 according to a first variation of the first embodiment:

FIGS. 5 (a) and 5 (b) are, respectively, a front view (FIG. 5 (a)) and a plan view (FIG. 5 (b)) of the magnetic measuring section 12 according to a third variation of the first embodiment:

FIG. 6 is a side view showing how the magnetic measuring section 12 according to the second embodiment is moved:

FIG. 7 is a plan view of the magnetic measuring section 12 according to the third embodiment; and

FIG. 8 is a perspective view of the magnetic measuring section 12 according to the fourth embodiment.

### DESCRIPTION OF THE PREFERRED EMBODIMENT

Preferred embodiments of the present invention will hereinafter be described with reference to the accompanying drawings.

### First Embodiment

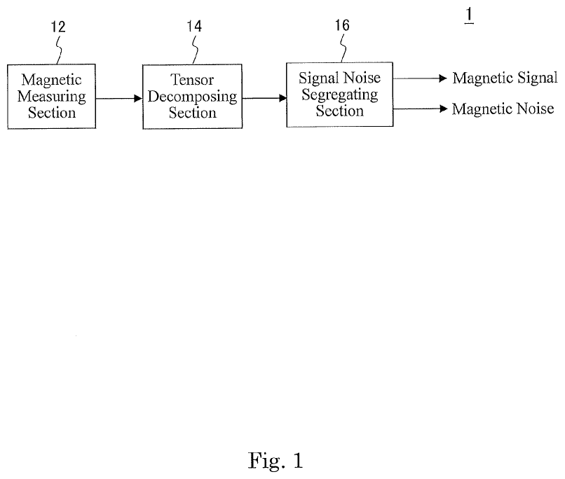

FIG. 1 is a functional block diagram showing the configuration of a magnetic signal noise measuring apparatus 1 according to a first embodiment of the present invention. The magnetic signal noise measuring apparatus 1 according to the first embodiment includes a magnetic measuring section 12, a tensor decomposing section 14, and a signal noise segregating section 16.

The magnetic measuring section 12 is arranged to measure magnetic noise and a magnetic signal generated by a magnetic signal source as a tensor of third or higher order (to be detailed below, though may be measured as a tensor of second order). It is noted that the magnetic noise and the magnetic signal each have a constant value. The magnetic noise is, for example, the geomagnetic field. One or two or more magnetic signal sources may also be provided.

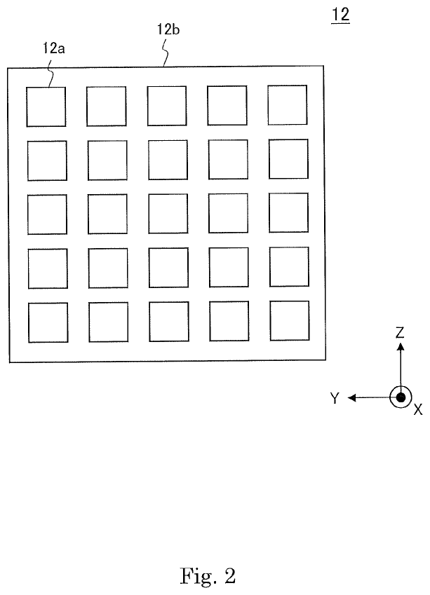

FIG. 2 is a plan view of the magnetic measuring section 12 according to the first embodiment. The magnetic measuring section 12 according to the first embodiment has magnetic sensors 12a and a substrate 12b. The magnetic sensors 12a are arranged on the substrate 12b. The magnetic measuring section 12 is a two-dimensional sensor array with the magnetic sensors 12a arranged in a first direction Y and a second direction Z that are orthogonal to each other. It is noted that the magnetic sensors 12a are arranged at the same intervals both in the first direction Y and the second direction Z. That is, (1) the magnetic sensors 12a are arranged at the same intervals in the first direction Y, (2) the magnetic sensors 12a are arranged at the same intervals in the second direction Z, and (3) the intervals in (1) are equal to the intervals in (2).

It is noted that embodiments of the present invention are described under the assumption that the magnetic sensors 12a are magnetically sensitized in the second direction Z (vertical direction). However, the magnetic sensors 12a may be magnetically sensitized in two or three axial directions.

In the first embodiment, the magnetic measuring section 12 is arranged to be moved in the third direction X during measurement. Note here that the third direction X is orthogonal to the first direction Y and the second direction Z.

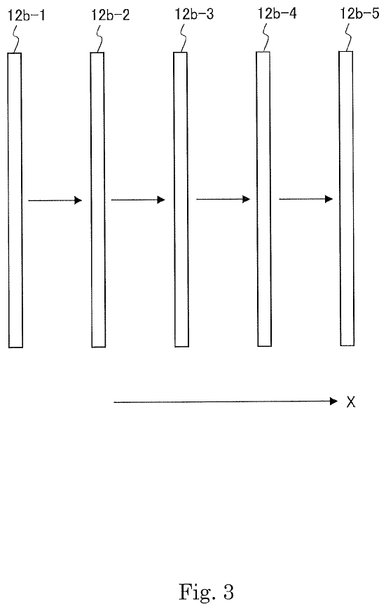

FIG. 3 is a side view showing how the magnetic measuring section 12 according to the first embodiment is moved. The substrate 12b of the magnetic measuring section 12 is arranged to be translated in the third direction X from a substrate position 12b-1 through a substrate position 12b-2, a substrate position 12b-3, and a substrate position 12b-4 to a substrate position 12b-5. The intervals between any two of the substrate positions 12b-1 to 12b-5 are also equal to the intervals between the magnetic sensors 12a in the first direction Y (and also the second direction Z).

As noted above, the magnetic measuring section 12 is arranged to measure magnetic noise and a magnetic signal output from the magnetic signal source as a tensor of third order associated with 5×5×5 (spatial positions). Note here that 5× 5×5 is merely an example and the size may not be equal in each of the axial directions. For example, tensor data may be obtained with sizes of 5×8×10 in the respective axial directions.

It is noted that the magnetic measuring section 12 may be arranged to measure magnetic noise and a magnetic signal as a tensor of third or higher order associated with a spatial position and time. For example, the magnetic measuring section 12 may be arranged to measure magnetic noise and a magnetic signal as a tensor of fourth (=3+1) order associated with a spatial position (having X, Y, and Z coordinates) (third order) and time (first order). For example, the magnetic measuring section 12 may alternatively be arranged to measure magnetic noise and a magnetic signal as a tensor of third (=2+1) order associated with a spatial position (having X and Y coordinates) (second order) and time (first order).

The tensor decomposing section 14 is arranged to tensor-decompose a measurement result from the magnetic measuring section 12. A method for tensor decomposition is well known and may employ, for example, CP decomposition, Tucker decomposition or block-term decomposition. It is noted that two or three or more results of tensor decomposition may be provided.

The signal noise segregating section 16 is arranged to segregate a decomposition result from the tensor decomposing section 14 into one representing the magnetic signal and one representing the magnetic noise.

When two results of tensor decomposition are provided, one decomposition result representing the magnetic signal and one decomposition result representing the magnetic noise are provided.

When three results of tensor decomposition are provided, one of the decomposition results represents the magnetic signal and the two others represent the magnetic noise, for example, one having a magnetic gradient direction in X direction and the other having a magnetic gradient direction in Z direction.

Next will be described an operation of the magnetic signal noise measuring apparatus 1 according to the first embodiment. Note here that the operation described below is under the assumption that a measurement result from the magnetic measuring section 12 is obtained as a tensor of third order associated with a spatial position (having X, Y, and Z coordinates), the tensor decomposition is CP decomposition, and two decomposition results are provided.

A measurement result from the magnetic measuring section 12 is expressed as in Formula (1) below:

$$χ = {\sum }_{s = 1}^{2} {λ}_{s} {a}_{s}^{( z )} ∘ {a}_{s}^{( x )} ∘ {a}_{s}^{( y )} \qquad ( 1 )$$

where

χ; measurement result from the magnetic measuring section 12 (tensor of third order),

aₛ^{(x)}, aₛ^{(y)}, aₛ^{(z)}: S-th (5, 1) vector,

∘: outer product.

The CP decomposition is equivalent to solving Formula (2) below:

$$minimize {‖ χ - {\sum }_{s = 1}^{2} {λ}_{s} {a}_{s}^{( z )} ∘ {a}_{s}^{( x )} ∘ {a}_{s}^{( y )} ‖}_{F}^{2} \qquad ( 2 )$$

The measurement result from the magnetic measuring section 12 (Formula (1)) is provided to and solved with Formula (2) in the tensor decomposing section 14 for tensor decomposition.

Matrices Aₓ, A_{y}, and A_{z}, which summarize the respective vectors in X, Y, and Z directions, are here defined as in Formulae (3), (4), and (5) below:

$${A}_{x} = ( \begin{matrix}{a}_{1}^{( x )} & {a}_{2}^{( x )}\end{matrix} ) \qquad ( 3 )$$

$${A}_{y} = ( \begin{matrix}{a}_{1}^{( y )} & {a}_{2}^{( y )}\end{matrix} ) \qquad ( 4 )$$

$${A}_{z} = ( \begin{matrix}{a}_{1}^{( z )} & {a}_{2}^{( z )}\end{matrix} ) \qquad ( 5 )$$

After initializing Aₓ and A_{y} with random values so that the norm of each column is 1, Formulae (6) to (12) below can be computed repeatedly until convergence to solve Formula (2) (i.e. to obtain Aₓ, A_{y}, and A_{z}). It is noted that the arrow in the formula means that the right value is assigned to the left.

$${A}_{z} ← {χ}_{( 1 )} ( {A}_{y} ⊙ {A}_{x} ) {( {A}_{y}^{T} {A}_{y} * {A}_{x}^{T} {A}_{x} )}^{†} \qquad ( 6 )$$

where

χ₍₁₎: mode-1 matricization

⊙: KR product

*: Hadamard product

T: transposition

†: Moore-Penrose generalized inverse

$${a}_{s}^{( z )} ← \frac{{a}_{s}^{( z )}}{‖ {a}_{s}^{( z )} ‖} \qquad ( 7 )$$

$${A}_{x} ← {χ}_{( 2 )} ( {A}_{y} ⊙ {A}_{z} ) {( {A}_{y}^{T} {A}_{y} * {A}_{z}^{T} {A}_{z} )}^{†} \qquad ( 8 )$$

where

χ₍₂₎: mode-2 matricization

$${a}_{s}^{( x )} ← \frac{{a}_{s}^{( x )}}{‖ {a}_{s}^{( x )} ‖} \qquad ( 9 )$$

$${A}_{y} ← {χ}_{( 3 )} ( {A}_{x} ⊙ {A}_{z} ) {( {A}_{x}^{T} {A}_{x} * {A}_{z}^{T} {A}_{z} )}^{†} \qquad ( 10 )$$

where

χ₍₃₎: mode-3 matricization

$${λ}_{s} ← ‖ {a}_{s}^{( y )} ‖ \qquad ( 11 )$$

$${a}_{s}^{( y )} ← \frac{{a}_{s}^{( y )}}{‖ {a}_{s}^{( y )} ‖} \qquad ( 12 )$$

The finally obtained Aₓ, A_{y}, A_{z}, and λₛ can be used with Formula (1) to perform tensor decomposition. That is, where the measurement result from the magnetic measuring section 12 (tensor of third order) is expressed as in Formula (13) below (through deformation on Formula (1)):

$$χ = {λ}_{1} {a}_{1}^{( z )} ∘ {a}_{1}^{( x )} ∘ {a}_{1}^{( y )} + {λ}_{2} {a}_{2}^{( z )} ∘ {a}_{2}^{( x )} ∘ {a}_{2}^{( y )} \qquad ( 13 )$$

the measurement result from the magnetic measuring section 12 (tensor of third order) can be decomposed into the first term on the right side of Formula (13) (the term to the left of +) and the second term on the right side of Formula (13) (the term to the right of +).

The signal noise segregating section 16 segregates the decomposition result from the tensor decomposing section 14 (the first and second terms on the right side of Formula (13)) into one representing the magnetic signal and one representing the magnetic noise. One of the first and second terms on the right side of Formula (13) represents the magnetic signal and the other represents the magnetic noise. If the magnetic noise is the geomagnetic field, the magnetic field due to the magnetic noise is detected throughout the space in which the magnetic field is measured. On the other hand, if one magnetic signal source is provided, the magnetic field due to the magnetic signal is detected only in the vicinity of the magnetic signal source. From this point of view, the decomposition result from the tensor decomposing section 14 can be segregated.

In accordance with the first embodiment, it is possible to isolate magnetic noise.

Note here that the magnetic measuring section 12 may be arranged to measure magnetic noise and a magnetic signal generated by a magnetic signal source as a tensor of second order. In this case, the magnetic measuring section 12 is not required to be moved in the third direction X and the magnetic field in YZ plane will only be measured (or the magnetic field will be measured as a tensor of second order (=1+1) associated with a spatial position (a tensor of first order (1×5) at a certain Z coordinate or a tensor of first order (5×1) at a certain Y coordinate) and time (first order)).

It is noted that various variations may be made to the first embodiment.

### <First Variation>

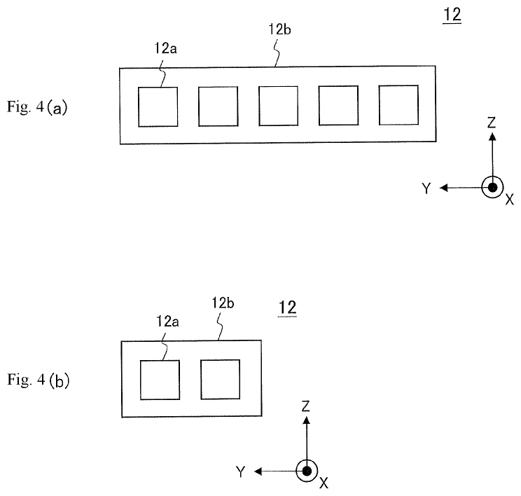

FIGS. 4 (a) and 4 (b) are plan views of the magnetic measuring section 12 according to a first variation of the first embodiment. FIG. 4 (a) is a plan view showing that five magnetic sensors 12a are arranged in Y direction. FIG. 4 (b) is a plan view showing that two magnetic sensors 12a are arranged in Y direction.

In the first variation, the magnetic measuring section 12 is a one-dimensional sensor array with the magnetic sensors 12a arranged in the first direction Y (though may be arranged in the second direction Z). The magnetic measuring section 12, which is just a one-dimensional sensor array as above, exhibits the same advantageous effects as the first embodiment.

Note here that the magnetic measuring section 12 shown in FIG. 4 (a) can be moved four times in Z direction to measure the magnetic field at positions indicated by 5×5 (Y×Z) coordinates. The magnetic measuring section 12 can then be moved in X direction and further moved four times in Z direction. Thus being moved repeatedly can lead to a tensor with 5×5×5.

The magnetic measuring section 12 shown in FIG. 4 (b) can also be moved repeatedly in Y direction to measure the magnetic field at positions indicated by 5×1 (Y×Z) coordinates. Further, the movement in Y direction is repeated for each movement in Z direction. Thus being moved repeatedly can lead to measurement of the magnetic field at positions indicated by 5×5 (Y×Z) coordinates. The magnetic measuring section 12 can then be moved in X direction and moved repeatedly in Y and Z directions as above to obtain a tensor with 5×5×5.

It is noted that the magnetic measuring section 12, if arranged to measure magnetic noise and a magnetic signal output from the magnetic signal source as a tensor of second order, is not required to be moved in the third direction X and the magnetic field in YZ plane will only be measured (or the magnetic field will be measured as a tensor of second order (=1+1) associated with a spatial position (Z coordinate) (first order) and time (first order)).

### <Second Variation>

In a second variation of the first embodiment, the magnetic measuring section 12 includes only one magnetic sensor. Even if the magnetic measuring section 12 may thus include only one magnetic sensor, moving the single magnetic sensor to 5×5×5 (or 5×5) coordinates allows a tensor with 5×5×5 (or 5×5) to be obtained, which exhibits the same advantageous effects as the first embodiment. It is noted that the single magnetic sensor may be moved to 5×1 coordinates and the result of measurement may be further associated with time to obtain a tensor of second order.

### <Third Variation>

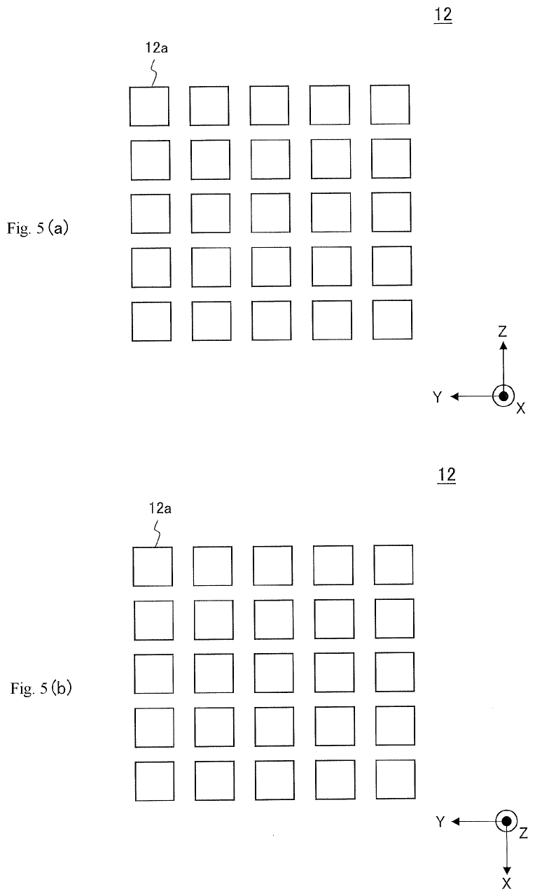

FIGS. 5 (a) and 5 (b) are, respectively, a front view (FIG. 5 (a)) and a plan view (FIG. 5 (b)) of the magnetic measuring section 12 according to a third variation of the first embodiment.

In the third variation, the magnetic measuring section 12 is a three-dimensional sensor array with magnetic sensors 12a arranged in the first direction Y, the second direction Z, and the third direction X that are orthogonal to each other. In the example shown in FIGS. 5 (a) and 5 (b), the magnetic sensors 12a are arranged in 5×5×5. This allows a tensor with 5×5×5 (or 5×5) to be obtained without the magnetic measuring section 12 being moved, which exhibits the same advantageous effects as the first embodiment. It is noted that measurement results from the magnetic sensors 12a at positions indicated by 5×1 coordinates may be further associated with time to obtain a tensor of second order.

It is noted that in the third variation, the magnetic sensors 12a may not be arranged in 5×5×5, but in, for example, 10×10×10 or 2×2×2, as long as forming a three-dimensional sensor array. Note here that the magnetic sensors 12a, if arranged in 2×2×2, are moved repeatedly in the first direction Y, the second direction Z, and the third direction X to obtain a tensor with 5×5×5. Alternatively, when the magnetic sensors 12a, if arranged in 2×2×2, are moved repeatedly in the first direction Y and the second direction Z, a measurement result from one of the magnetic sensors 12a provides a tensor with 5×5. Alternatively, when the magnetic sensors 12a are moved repeatedly in the first direction Y and the second direction Z, a measurement result from one of the magnetic sensors 12a provides a tensor of first order (1×5) at a certain Z coordinate or a tensor of first order (5×1) at a certain Y coordinate. The result of measurement may be further associated with time to obtain a tensor of second order.

### <Fourth Variation>

In a fourth variation of the first embodiment, the magnetic noise and the magnetic signal change over time. For example, the magnetic noise may be generated from an alternating-current utility power source.

### Second Embodiment

The magnetic signal noise measuring apparatus 1 according to a second embodiment has a different direction of movement (rotational movement about the Z axis) of the magnetic measuring section 12 than the magnetic signal noise measuring apparatus 1 according to the first embodiment.

The magnetic signal noise measuring apparatus 1 according to the second embodiment includes a magnetic measuring section 12, a tensor decomposing section 14, and a signal noise segregating section 16. The tensor decomposing section 14 and the signal noise segregating section 16 according to the second embodiment are identical to those in the first embodiment and will not be described.

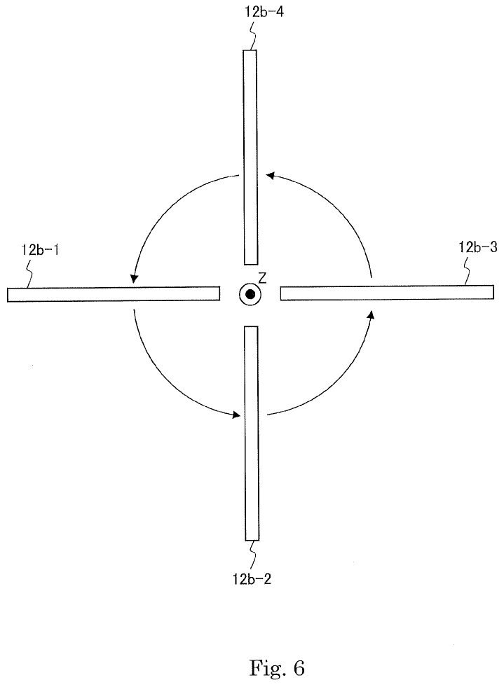

FIG. 6 is a side view showing how the magnetic measuring section 12 according to the second embodiment is moved. In the second embodiment, the substrate 12b of the magnetic measuring section 12 (which may be one as shown in any of FIGS. 2 and 4 (a)) is arranged to be rotated about a rotation axis running in the second direction Z from a substrate position 12b-1 through a substrate position 12b-2, a substrate position 12b-3, and a substrate position 12b-4 to the substrate position 12b-1 for measurement by the magnetic measuring section 12. Note here that the substrate 12b may be rotated about a rotation axis running in the first direction Y.

It is noted that the substrate 12b may be rotated clockwise or at different angular intervals (e.g. 10-degree intervals, 36-degree intervals, 45-degree intervals, etc.), though rotated counterclockwise at 90-degree intervals in FIG. 6.

Also, the side of the substrate 12b nearer the rotation axis (in the first direction Y) may be on the rotation axis, though separated from the rotation axis in FIG. 6.

Further, the substrate 12b may be rotated less than 360 degrees, though rotated 360 degrees back to the original position (substrate position 12b-1) in FIG. 6. For example, the substrate 12b may be rotated from the substrate position 12b-1 to the substrate position 12b-2 and stopped there (90-degree rotation) or may be rotated 120 degrees.

In accordance with the second embodiment, it is possible to isolate magnetic noise, as is the case in the first embodiment.

It is noted that the magnetic signal noise measuring apparatus 1 according to the second embodiment is useful for inspecting columnar structures. A measurement may be made around a columnar structure (e.g. a utility pole, a signpost, a pipe, etc.) with the substrate 12b rotated therearound to estimate the position of a magnetic body, which is useful for sensing fracture and/or corrosion, for example.

Note here that the magnetic measuring section 12 may be arranged to measure magnetic noise and a magnetic signal generated by a magnetic signal source as a tensor of second order. In this case, the magnetic measuring section 12 is not required to be rotated and the magnetic field in YZ plane will only be measured.

### Third Embodiment

The magnetic signal noise measuring apparatus 1 according to a third embodiment has a different manner of arrangement (radial arrangement) of magnetic sensors in the magnetic measuring section 12 than the magnetic signal noise measuring apparatus 1 according to the first embodiment.

The magnetic signal noise measuring apparatus 1 according to the third embodiment includes a magnetic measuring section 12, a tensor decomposing section 14, and a signal noise segregating section 16. The tensor decomposing section 14 and the signal noise segregating section 16 according to the third embodiment are identical to those in the first embodiment and will not be described.

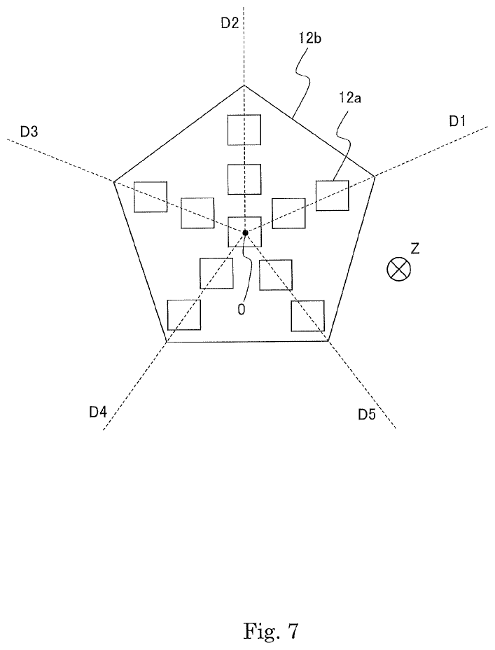

FIG. 7 is a plan view of the magnetic measuring section 12 according to the third embodiment. The magnetic measuring section 12 has magnetic sensors 12a and a substrate 12b. The magnetic sensors 12a are arranged on the substrate 12b. The magnetic sensors 12a are arranged on a predetermined plane (plane of the page of FIG. 7) and in three or more directions D1, D2, D3, D4, and D5 intersecting with each other at one point 0. It is noted that the intersecting directions D1, D2, D3, D4, and D5 are arranged at 72-degree intervals. Also, the number of intersecting directions is not limited to five, but is arbitrary as long as three or more.

In the third embodiment, a measurement is made with the magnetic measuring section 12 moved in the second direction Z (orthogonal to the predetermined plane (plane of the page of FIG. 7)).

In accordance with the third embodiment, it is possible to isolate magnetic noise, as is the case in the first embodiment.

It is noted that the magnetic signal noise measuring apparatus 1 according to the third embodiment is useful for probing inside circular pipes (e.g. waterworks and sewerage pipes).

Note here that the magnetic measuring section 12 may be arranged to measure magnetic noise and a magnetic signal generated by a magnetic signal source as a tensor of second order. In this case, the magnetic measuring section 12 is not required to be moved in the second direction Z and the magnetic field in rθ plane will only be measured (where “r” represents the distance from the one point 0 and θ represents the angle between the intersecting direction and any direction in the predetermined plane).

### Fourth Embodiment

The magnetic signal noise measuring apparatus 1 according to a fourth embodiment has a different manner of arrangement (on a curved plane) of magnetic sensors in the magnetic measuring section 12 than the magnetic signal noise measuring apparatus 1 according to the first embodiment.

The magnetic signal noise measuring apparatus 1 according to the fourth embodiment includes a magnetic measuring section 12, a tensor decomposing section 14, and a signal noise segregating section 16. The tensor decomposing section 14 and the signal noise segregating section 16 according to the fourth embodiment are identical to those in the first embodiment and will not be described.

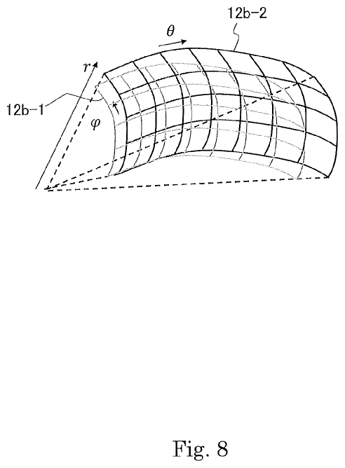

FIG. 8 is a perspective view of the magnetic measuring section 12 according to the fourth embodiment. The magnetic measuring section 12 according to the fourth embodiment is arranged to make a measurement with the substrate 12b moved from a substrate position 12b-1 to a substrate position 12b-2. It is noted that the substrate 12b has a curved plane and any position on the substrate 12b can be represented by coordinates such as (θ, φ, r). Multiple magnetic sensors 12a (not shown) are each positioned at each of the grids (4×7) on the curved plane (substrate 12b) in FIG. 8.

It is noted that the geometry of the curved plane (substrate 12b) is not limited to that shown in FIG. 8, but may be, for example, semispherical or spherical.

In accordance with the fourth embodiment, it is possible to isolate magnetic noise, as is the case in the first embodiment.

It is noted that the magnetic signal noise measuring apparatus 1 according to the fourth embodiment is applicable to magnetic field measurement with a helmet shape such as magnetoencephalography.

Note here that the magnetic measuring section 12 may be arranged to measure magnetic noise and a magnetic signal generated by a magnetic signal source as a tensor of second order. In this case, the magnetic measuring section 12 is not required to be moved and the magnetic field in θφ plane will only be measured (where θ and φ represent the directions of curves orthogonal to each other in a curved plane).

The above-described embodiments can also be implemented as follows. A medium (USB memory, CD-ROM, or the like) with a program recorded thereon for achieving the above-described sections (e.g. tensor decomposing section 14 and signal noise segregating section 16) may be read by a computer including a CPU, a hard disk, and a medium reader and installed in the hard disk. Such an approach can also perform the above-described functions.

### DESCRIPTION OF REFERENCE NUMERALS

1 Magnetic Signal Noise Measuring Apparatus
12 Magnetic Measuring Section
12a Magnetic Sensor
12b Substrate
12b-1, 12b-2, 12b-3, 12b-4, 12b-5 Substrate Positions
14 Tensor Decomposing Section
16 Signal Noise Segregating Section
Y First Direction
Z Second Direction
X Third Direction
D1, D2, D3, D4, D5 Intersecting Directions

What is claimed is:

1. A magnetic signal noise measuring apparatus, comprising:
a magnetic measuring section arranged to measure magnetic noise and a magnetic signal generated by a magnetic signal source as a tensor of second or higher order;
a tensor decomposing section arranged to tensor-decompose a measurement result from the magnetic measuring section; and
a signal noise segregating section arranged to segregate a decomposition result from the tensor decomposing section into one representing the magnetic signal and one representing the magnetic noise.

2. The magnetic signal noise measuring apparatus according to claim 1, wherein
the magnetic measuring section is a two-dimensional sensor array with magnetic sensors arranged in a first direction and a second direction that are orthogonal to each other.

3. The magnetic signal noise measuring apparatus according to claim 2, wherein
the tensor is of third or higher order, and
the magnetic measuring section is arranged to be moved in a third direction orthogonal to the first direction and the second direction during measurement.

4. The magnetic signal noise measuring apparatus according to claim 1, wherein
the magnetic measuring section is a one-dimensional sensor array with magnetic sensors arranged in one of a first direction and a second direction that are orthogonal to each other.

5. The magnetic signal noise measuring apparatus according to claim 2, wherein
the tensor is of third or higher order, and
the magnetic measuring section is arranged to be rotated about a rotation axis running in the first direction or the second direction during measurement.

6. The magnetic signal noise measuring apparatus according to claim 1, wherein
the magnetic measuring section includes magnetic sensors arranged on a predetermined plane and in three or more directions intersecting with each other at one point.

7. The magnetic signal noise measuring apparatus according to claim 6, wherein
the tensor is of third or higher order, and
the magnetic measuring section is arranged to be moved in a direction orthogonal to the plane during measurement.

8. The magnetic signal noise measuring apparatus according to claim 1, wherein
the magnetic measuring section includes a single magnetic sensor.

9. The magnetic signal noise measuring apparatus according to claim 1, wherein
the magnetic measuring section is a three-dimensional sensor array with magnetic sensors arranged in a first direction, a second direction, and a third direction that are orthogonal to each other.

10. The magnetic signal noise measuring apparatus according to claim 1, wherein
the magnetic measuring section includes a plurality of magnetic sensors arranged on a curved plane.

11. The magnetic signal noise measuring apparatus according to claim 1, wherein
the tensor is of third or higher order and provides a result of measurement of the magnetic signal and the magnetic noise associated with a spatial position or the position and time.

12. The magnetic signal noise measuring apparatus according to claim 1, wherein
the tensor decomposing section is arranged to provide three or more decomposition results, and
a plurality of the decomposition results are ones representing the magnetic noise having magnetic gradient directions different from each other.

13. The magnetic signal noise measuring apparatus according to claim 1, wherein
the magnetic noise and the magnetic signal each have a constant value.

14. The magnetic signal noise measuring apparatus according to claim 1, wherein
the magnetic noise and the magnetic signal change over time.

15. A magnetic signal noise measuring method with using a magnetic signal noise measuring apparatus including a magnetic measuring section arranged to measure magnetic noise and a magnetic signal generated by a magnetic signal source as a tensor of second or higher order, comprising:
tensor-decomposing a measurement result from the magnetic measuring section; and
segregating a decomposition result from the tensor-decomposing of the measurement result into one representing the magnetic signal and one representing the magnetic noise.

16. A non-transitory computer-readable medium including a program of instructions for execution by a computer to perform a magnetic signal noise measuring process with using a magnetic signal noise measuring apparatus including a magnetic measuring section arranged to measure magnetic noise and a magnetic signal generated by a magnetic signal source as a tensor of second or higher order, said magnetic signal noise measuring process comprising:
tensor-decomposing a measurement result from the magnetic measuring section; and
segregating a decomposition result from the tensor-decomposing of the measurement result into one representing the magnetic signal and one representing the magnetic noise.
